(19) United States
(12) Patent Application Publication
(10) Pub. No.: US 2019/0214372 A1
(43) Pub. Date: Jul. 11, 2019

(54) METHOD FOR FABRICATING ELECTRONIC PACKAGE HAVING A SHIELDING LAYER

(71) Applicant: Siliconware Precision Industries Co., Ltd., Taichung City (TW)

(72) Inventors: Hong-Da Chang, Taichung (TW); Yih-Jenn Jiang, Taichung (TW)

(21) Appl. No.: 16/356,589

(22) Filed: Mar. 18, 2019

Related U.S. Application Data
(62) Division of application No. 15/494,814, filed on Apr. 24, 2017.

(30) Foreign Application Priority Data
Sep. 2, 2016 (TW) 105128409

(51) Int. Cl. H01L 25/065; H01L 25/10; H01L 23/552; H01L 23/00; H01L 23/31; H01L 21/768; H01L 21/683; H01L 21/56; H01L 25/00

(52) U.S. Cl. CPC H01L 25/0657; H01L 2224/16227; H01L 23/552; H01L 24/17; H01L 24/06; H01L 24/03; H01L 23/3114; H01L 21/76885; H01L 21/6835; H01L 21/568; H01L 25/50; H01L 2225/06572; H01L 2225/06548; H01L 2225/06537; H01L 2924/19105; H01L 2225/06586; H01L 2224/0401; H01L 2221/68359; H01L 2225/06517; H01L 25/105

(57) ABSTRACT

An electronic package is provided, including: a first circuit structure; an electronic component and a conductive pillar disposed on the first circuit structure; an encapsulation layer encapsulating the electronic component and the conductive pillar; a second circuit structure disposed on the encapsulation layer; and a shielding layer encapsulating the first circuit structure, a side surface of the encapsulation layer, and a side surface of the second circuit structure. The electronic component is surrounded by the shielding layer, and is protected from electromagnetic interference. A method for fabricating the electronic package is also provided.

### BACKGROUND

### 1. Technical Field

The present disclosure relates to package techniques, and, more particularly, to a semiconductor package that avoids electromagnetic interference and a method for fabricating the same.

### 2. Description of the Prior Art

With the rapid development of electronic industry, modern electronic products have a variety of functionalities. In order to meet the miniaturization of package requirement for an electronic package, a wafer level packaging (WLP) technique is brought to the market.

FIGS. 1A-1E are cross-sectional diagrams of a wafer-leveled semiconductor package 1 according to the prior art.

As shown in FIG. 1A, a thermal release tape 100 is formed on a carrier 10.

Then, a plurality of semiconductor components 11 are disposed on the thermal release tape 100. Each of the semiconductor components 11 has opposing active and inactive surfaces 11a and 11b, a plurality of electrode pads 110 are disposed on each of the active surfaces 11a, and the active surfaces 11a are adhered to the thermal release tape 100.

As shown in FIG. 1B, a packaging resin 14 is formed on the thermal release tape 100 to package the semiconductor components 11.

As shown in FIG. 1C, the packaging resin 14 is baked to cure the thermal release tape 100, and remove the thermal release tape 100 and the carrier 10 to expose the active surface 11a of the semiconductor components 11.

As shown in FIG. 1D, a circuit structure 16 is disposed on the packaging resin 14 and the active surface 11a of the semiconductor components 11, and electrically connected to the electrode pads 110. Then, an insulation protection layer 18 is formed on the circuit structure 16, with a portion of a surface of the circuit structure 16 exposed from the insulation protection layer 18, for conductive elements 17 such as solder balls to be combined therewith.

As shown in FIG. 1E, a singulation process is performed along a cutting path L shown in FIG. 1D to obtain a plurality of semiconductor packages 1.

However, in the prior art, since having no structure that shields electromagnetic interference (EMI), the semiconductor packages 1 in operation is likely affected by the EMI, and has its electric performance affected.

Therefore, how to overcome the problems of the prior art is becoming an urgent issue in the art.

### SUMMARY

In view of the problems of the prior art, the present disclosure provides an electronic package, comprising: a first circuit structure having opposing first and second sides, a conductive pillar formed on the first side and electrically connected to the first circuit structure; a first electronic component disposed on the first side of the first circuit structure; an encapsulation layer formed on the first side of the first circuit structure and encapsulating the first electronic component and the conductive pillar, with a portion of a surface of the first electronic component and an end surface of the conductive pillar exposed from the encapsulation layer; a second circuit structure formed on the encapsulation layer and electrically connected to the conductive pillar and the first electronic component; and a shielding layer formed on the second side of the first circuit structure and extending to a side surface of the first circuit structure, a side surface of the encapsulation layer, and a side surface of the second circuit structure.

The present disclosure further provides an electronic package, comprising: a first circuit structure having opposing first and second sides, and a conductive pillar formed on the first side and electrically connected to the first circuit structure; a first electronic component disposed on the first side of the first circuit structure; an encapsulation layer formed on the first side of the first circuit structure and encapsulating the first electronic component and the conductive pillar, with a portion of a surface of the first electronic component and an end surface of the conductive pillar exposed from the encapsulation layer; a second circuit structure formed on the encapsulation layer and electrically connected to the conductive pillar and the first electronic component; a second electronic component disposed on the second side of the first circuit structure; a packaging layer formed on the second side of the first circuit structure and encapsulating the second electronic component; and a shielding layer formed on the packaging layer and extending to a side surface of the first circuit structure, a side surface of the encapsulation layer, and a side surface of the second circuit structure.

The present disclosure also provides a method for fabricating an electronic package, comprising: providing a first circuit structure having opposing first and second sides; forming a conductive pillar on the first side of the first circuit structure, with the conductive pillar electrically connected to the first circuit structure; and disposing a first electronic component on the first side of the first circuit structure; forming on the first side of the first circuit structure an encapsulation layer encapsulating the first electronic component and the conductive pillar, with a portion of a surface of the first electronic component and an end surface of the conductive pillar exposed from the encapsulation layer; forming a second circuit structure on the encapsulation layer, with the second circuit structure electrically connected to the conductive pillar and the first electronic component; disposing a second electronic component on the second side of the first circuit structure; forming on the second side of the first circuit structure a packaging layer encapsulating the second electronic component; and forming on the packaging layer a shielding layer extending to a side surface of the first circuit structure, a side surface of the encapsulation layer, and a side surface of the second circuit structure.

In an embodiment, the shielding layer is electrically connected to the first circuit structure.

In an embodiment, the shielding layer is electrically connected to the second circuit structure.

In an embodiment, the shielding layer is electrically connected to the first circuit structure and the second circuit structure.

In an embodiment, the second circuit structure is exposed from the packaging layer.

In an embodiment, the electronic package further comprises a plurality of conductive elements formed on the second circuit structure.

It is known from the above that in an electronic package and a method for fabricating the same according to the present disclosure, the first electronic component and/or the second electronic component is surrounded by the shielding layer. Therefore, when the electronic package is in operation, the first electronic component and/or the second electronic component is not affected by electromagnetic interference. Compared with the prior art, the electronic package according to the present disclosure has its electric functionalities functioning normally.

### BRIEF DESCRIPTION OF THE DRAWINGS

The disclosure can be more fully understood by reading the following detailed description of the embodiments, with reference made to the accompanying drawings, wherein:

FIGS. 1A-1E are cross-sectional diagrams of a semiconductor package according to the prior art;

FIGS. 2A-2F are cross-sectional diagrams illustrating a method for fabricating an electronic package according to the present disclosure;

FIGS. 2F′ and 2F″ are cross-sectional diagrams illustrating another method for fabricating an electronic package according to the present disclosure; and

FIGS. 3A and 3B are cross-sectional diagrams of an electronic package of another different embodiment according to the present disclosure.

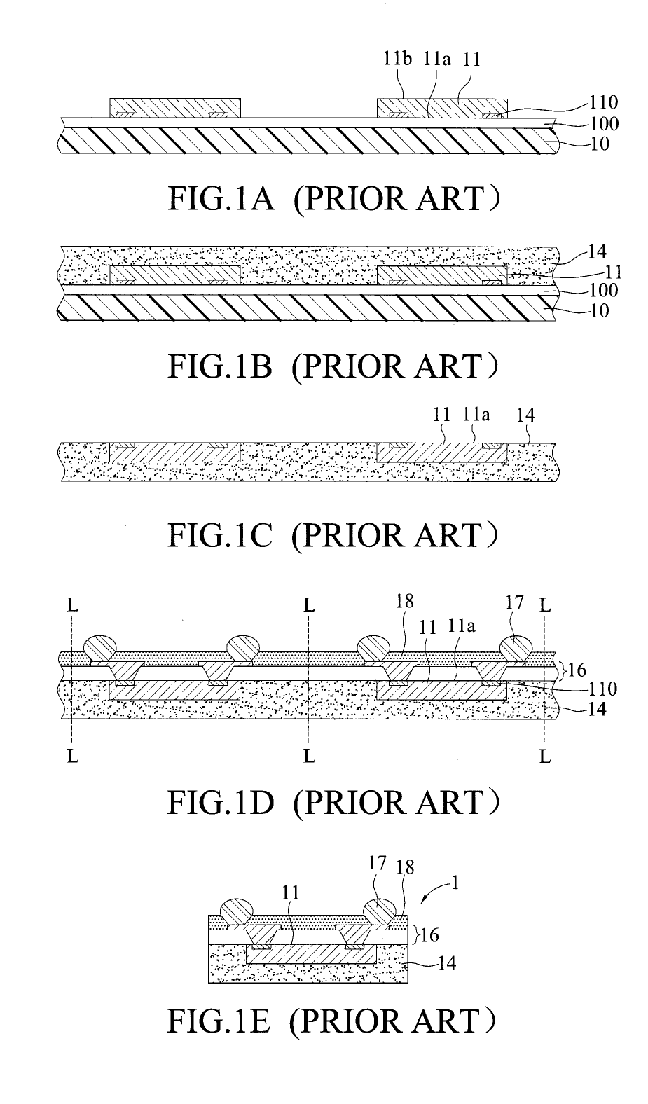

### DETAILED DESCRIPTIONS

The following illustrative embodiments are provided to illustrate the disclosure of the present disclosure. These and other advantages and effects can be apparently understood by those in the art after reading the disclosure of this specification. The present disclosure can also be performed or applied by other different embodiments.

It shall be noted that the illustrated structures, proportions, and sizes of the drawings of the present application are merely used for corresponding to the disclosure of the specification for one skilled in the art to understand and read. They do not serve as limiting conditions for limiting the scope of enablement of the present application; accordingly, they do not contribute substantial significance technically. Any modification of a structure, change of proportional relation, or adjustment of size still falls within the scope of the disclosure of the present application under the circumstance of no influence being brought about on the efficacy and purpose of the present application. Meanwhile, the terms such as “on”, “first”, “second” and “a” recited in the specification are used for clarity of the description and are not used to limit the scope of enablement of the present application. Changes or adjustments of relative relations thereof shall be deemed as within the scope of enablement of the present application under the circumstance of no substantial change of the technical disclosure.

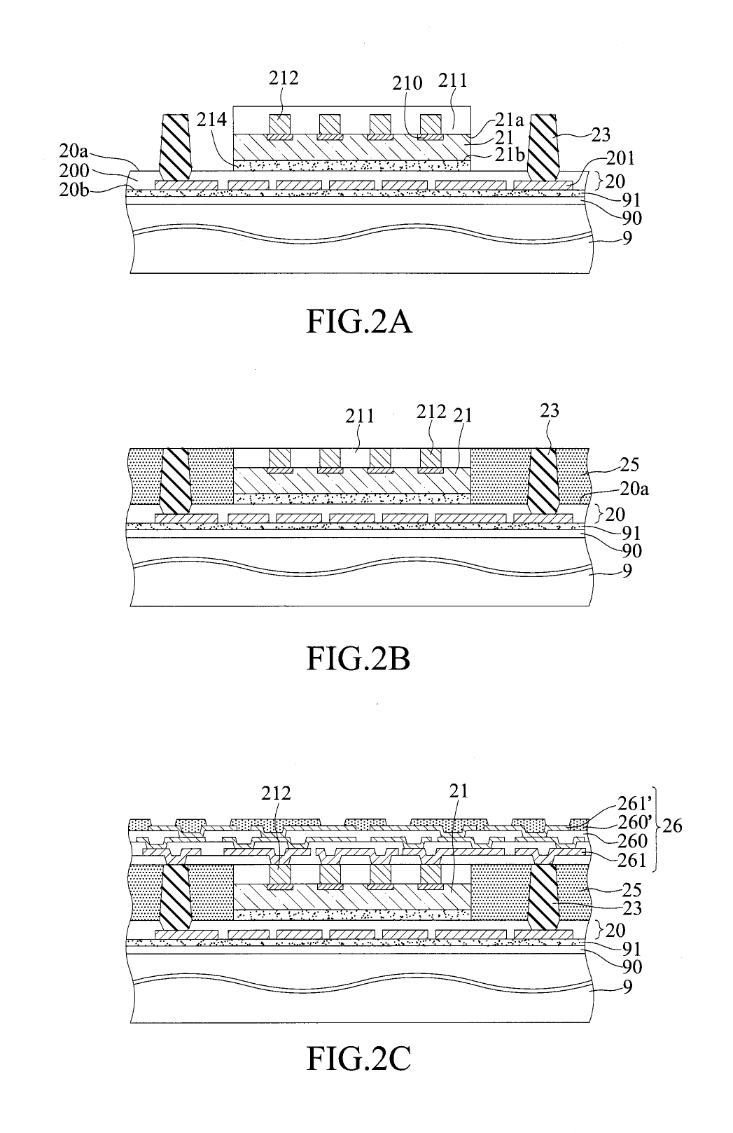

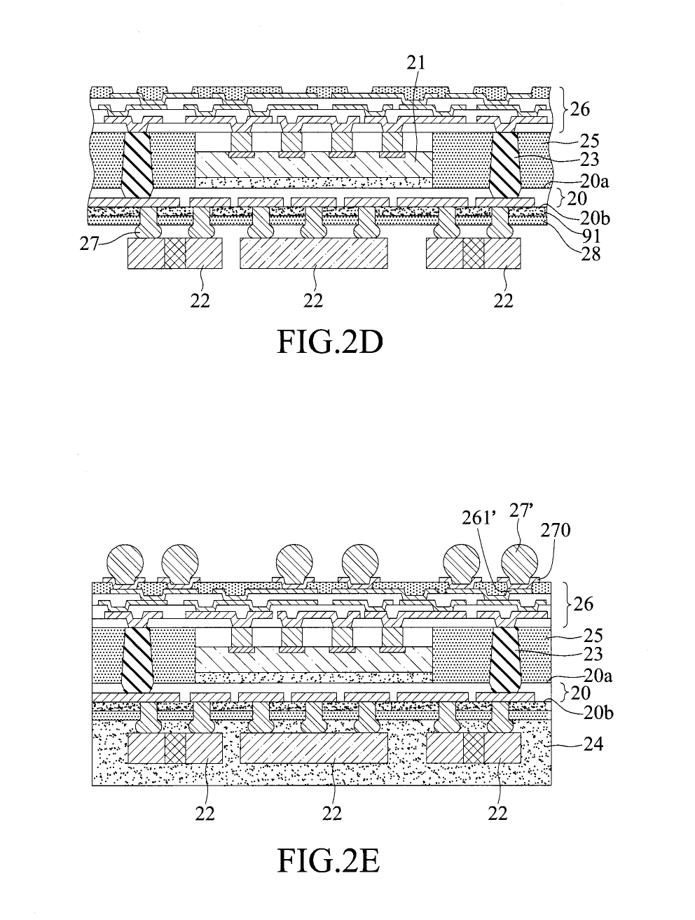

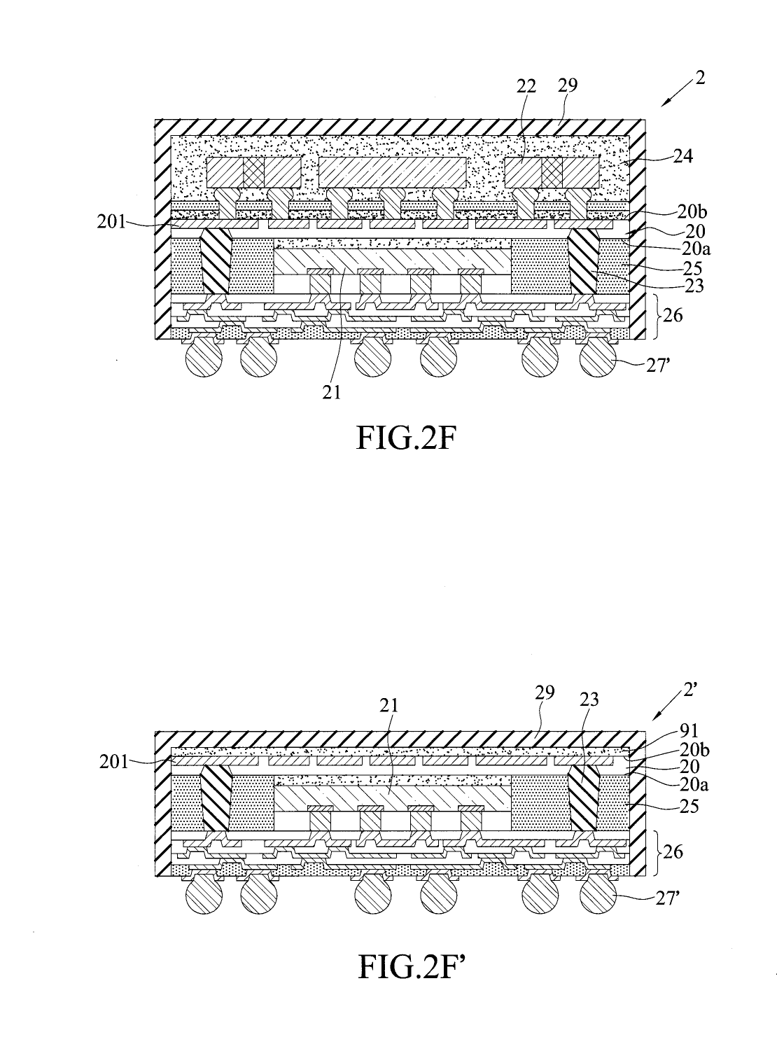

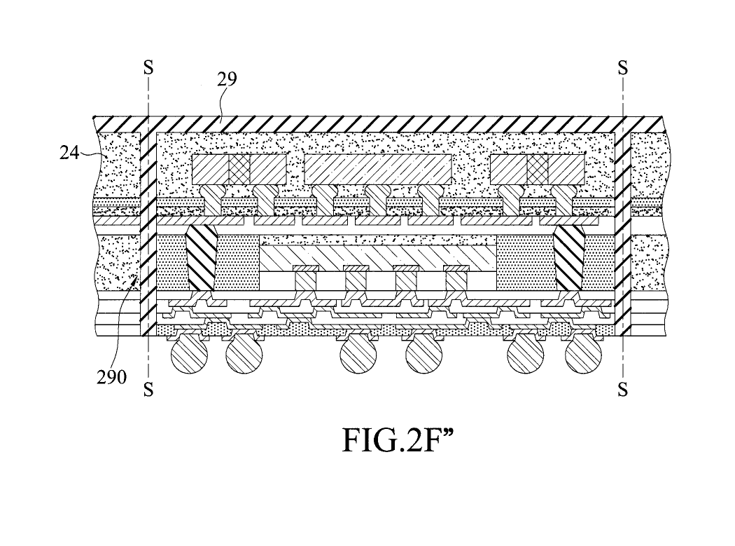

FIGS. 2A-2F are cross-sectional diagrams illustrating a method for fabricating an electronic package 2 according to the present disclosure.

As shown in FIG. 2A, a first circuit structure 20 is combined with a carrying board 9. The first circuit structure 20 has opposing first and second sides 20a and 20b. The second side 20b of the first circuit structure 20 is combined with the carrying board 9. Then, a plurality of conductive pillar 23 are disposed on the first side 20a and electrically connected to the first circuit structure 20. A first electronic component 21 is disposed on the first side 20a of the first circuit structure 20. A plurality of conductive members 212 are combined with and electrically connected to the first electronic component 21. In an embodiment, the conductive members 212 are, but not limited to be, in the shape of a round ball such as a solder ball, in the shape of a pillar, such as a copper pillar and a solder bump, or in the shape of a stud fabricated by a wire bonder.

In an embodiment, the first circuit structure 20 comprises at least one first insulation layer 200 and a first redistribution layer (RDL) 201 formed on the first insulation layer 200. In an embodiment, the first redistribution layer 201 is made of copper, and the first insulation layer 200 is made of a dielectric material, such as Polybenzoxazole (PBO), Polyimide (PI), or Prepre (PP).

In an embodiment, the carrying board 9 is a round board made of a semiconductor material, and is applied thereon with a release layer 90 and a combination layer 91 sequentially, for the first circuit structure 20 to be disposed on the combination layer 91.

The conductive pillar 23 is disposed on the first redistribution layer 201 and electrically connected to the first redistribution layer 201. In an embodiment, the conductive pillar 23 is made of metal such as copper, or a solder material.

In an embodiment, the first electronic component 21 is an active component, a passive component, or a combination thereof. In another embodiment, the active component is a semiconductor chip, and the passive component is a resistor, a capacitor or an inductor. In an embodiment, the first electronic component 21 is a semiconductor chip, and has opposing active and inactive surfaces 21a and 21b. The inactive surface 21b of the first electronic component 21 is adhered via a combination layer 214 to the first sides 20a of the first circuit structure 20. The active surface 21a has a plurality of electrode pads 210. The conductive members 212 are formed on the electrode pads 210. An insulation layer 211 is formed on the active surface 21a and encapsulates the electrode pads 210 and the conductive members 212. In an embodiment, the conductive members 212 are exposed from the insulation layer 211.

As shown in FIG. 2B, an encapsulation layer 25 is formed on the first side 20a of the first circuit structure 20, and encapsulates the first electronic component 21, the conductive members 212 and the conductive pillars 23. A leveling process is performed to level a surface of the encapsulation layer 25 with a surface of the insulation layer 211, an end surface of the conductive pillar 23, and an end surface of the conductive member 212, with the surface of the insulation layer 211, the end surface of the conductive pillar 23 and the end surface of the conductive member 212 exposed from the encapsulation layer 25.

In an embodiment, the encapsulation layer 25 is an insulation material such as packaging resin of epoxy resin, and can be formed on the first sides 20a of the first circuit structure 20 by lamination or molding processes.

According to the leveling process, a portion of the conductive pillar 23, a portion of the insulation layer 211 (including a portion of the conductive member 212 on demand), and a portion of the encapsulation layer 25 are removed in a grounding process.

It should be understood that if the conductive members 212 are exposed from the insulation layer 211, the removal of the portion of the insulation layer 211 enables the conductive members 212 to be exposed from the encapsulation layer 25 (the portion of the insulation layer 211 and the portion of the conductive member 212 can also be removed at the same time on demand, allowing the conductive members 212 to be exposed from the encapsulation layer 25).

As shown in FIG. 2C, a second circuit structure 26 is formed on the encapsulation layer 25 and electrically connected to the conductive pillar 23 and the conductive member 212.

In an embodiment, the second circuit structure 26 comprises a plurality of second insulation layers 260 and 260′ and a plurality of second redistribution layers (RDL) 261 and 261′ formed on the second insulation layer 260 and 260′. The outermost one of the second insulation layers 260′ serves as a solder mask layer, and the outermost one of the second redistribution layers 261′ is exposed from the solder mask layer. Alternatively, the second circuit structure 26 comprises a single second insulation layer 260 and a single second redistribution layer 261.

In an embodiment, the second redistribution layers 261 and 261′ are made of copper, and the second insulation layers 260 and 260′ are made of a dielectric material, such as PBO, Polyimide (PI) and Prepreg (PP).

As shown in FIG. 2D, the carrying board 9 and the release layer 90 thereon are removed. Then, a plurality of conductive elements 27 such as solder balls are formed on the second side 20b of the first circuit structure 20, for at least one second electronic component 22 to be disposed thereon.

In an embodiment, the second electronic component 22 is an active component such as a semiconductor chip, a passive component, such as a resistor, a capacitor and an inductor, and a combination thereof.

Optionally, an insulation protection layer 28 such as a solder mask layer is formed on the second side 20b of the first circuit structure 20 (or the combination layer 91), and a plurality of openings are formed on the insulation protection layer 28 and the combination layer 91, with a portion of a surface of the first redistribution layer 201 exposed from the openings, for the conductive elements 27 to be combined therewith. Alternatively, the insulation protection layer 28 is not formed, and a plurality of openings are directly formed on the combination layer 91 instead, with a portion of a surface of the first redistribution layer 201 exposed from the openings, for the conductive elements 27 to be combined therewith.

As shown in FIG. 2E, after a singulation process is performed, a packaging layer 24 is formed on the second side 20b of the first circuit structure 20 and encapsulates the second electronic component 22. Then, a plurality of conductive elements 27′ such as solder balls are formed on the outermost one of the second redistribution layers 261′, for an electronic device (not shown) such as a package structure and a chip to be disposed thereon.

In an embodiment, an Under Bump Metallurgy (UBM) is formed on the outermost one of the second redistribution layers 261′, for the conductive elements 27′ to be combined therewith.

As shown in FIG. 2F, a shielding layer 29 is formed on the packaging layer 24, and extends to a side surface of the first circuit structure 20, a side surface of the encapsulation layer 25, and a side surface of the second circuit structure 26.

In an embodiment, the shielding layer 29 is made of metal, and is electrically connected to the first redistribution layer 201 of the first circuit structure 20.

In another method, for the electronic package 2′ shown in FIG. 2F′, after the process of FIG. 2C is performed, the carrying board 9 and the release layer 90 thereon are removed, and a shielding layer 29 electrically connected to the first redistribution layer 201 of the first circuit structure 20 is formed on the second side 20b of the first circuit structure 20 (or on the combination layer 91) and extends to the side surface of the first circuit structure 20, the side surface of the encapsulation layer 25, and the side surface of the second circuit structure 26.

As shown in FIG. 2F″, in another method such as a mass production process, a plurality of grooves 290 are formed on the packaging layer 24 and penetrate the top and bottom sides of the structure, the shielding layer 29 is then formed in the grooves 290, and a singulation process is performed along a cutting path S (the cutting path S passing through the grooves 290) shown in FIG. 2F″ to obtain the electronic package 2 shown in FIG. 2F.

In the electronic package 2, 2′ according to the present disclosure, the first electronic component 21 or the second electronic component 22 is surrounded by the shielding layer 29. Therefore, when the electronic package 2, 2′ is in operation, the first electronic component 21 or the second electronic component 22 will not be affected by EMI, and the electronic package 2, 2′ can have its electric functionalities functioning normally and electric performance unaffected.

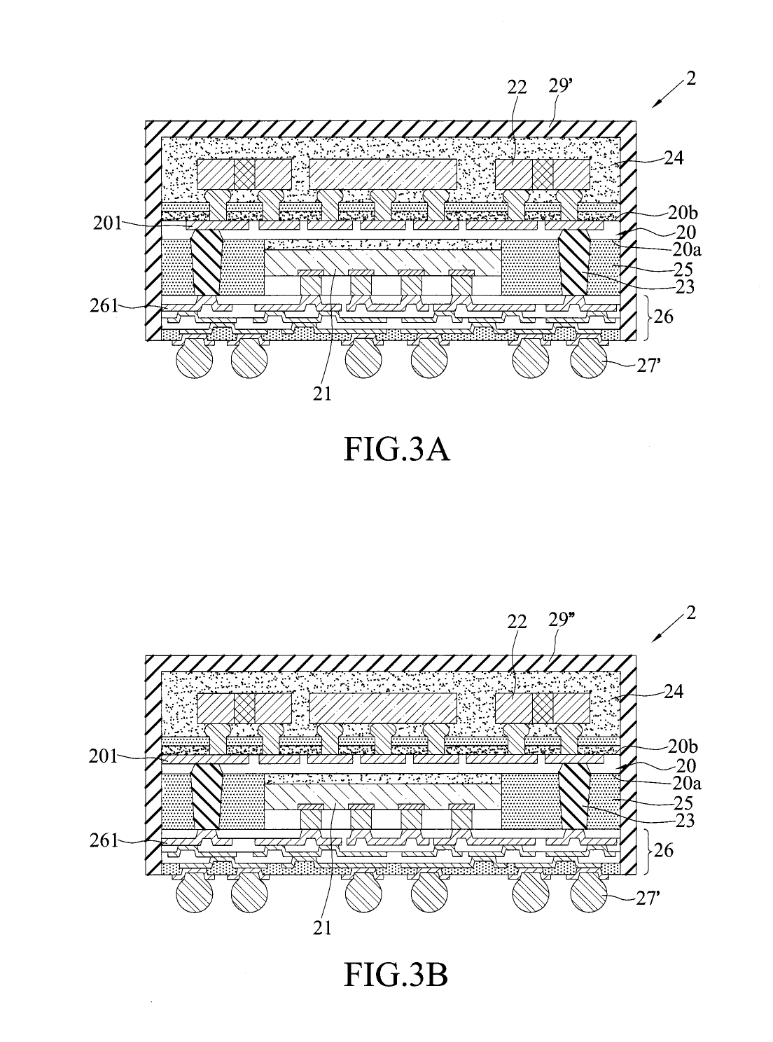

In an embodiment, the shielding layer 29 can be grounded via the first redistribution layer 201 of the first circuit structure 21. In another embodiment, as shown in FIG. 3A, the shielding layer 29′ is electrically connected to the second redistribution layer 261 of the second circuit structure 26, and is grounded via the second redistribution layer 261 of the second circuit structure 26. In yet another embodiment, as shown in FIG. 3B, the shielding layer 29″ is electrically connected to the first redistribution layer 201 and the second redistribution layer 261, and is grounded via the first redistribution layer 201 and the second redistribution layer 261.

It should be understood that the first electronic component 21 can be grounded via the second circuit structure 26 (as shown in FIG. 3A or FIG. 3B), or grounded via the second circuit structure 26, the conductive pillar 23 and the first circuit structure 20 (as shown in FIG. 2F or FIG. 3B). In another embodiment, the second electronic component 22 can be grounded via the first circuit structure 20 (as shown in FIG. 2F or FIG. 3B), or grounded via the first circuit structure 20, the conductive pillar 23 and the second circuit structure 26 (as shown in FIG. 3A or FIG. 3B).

The present disclosure also provides an electronic package 2, comprising: a first circuit structure 20, a first electronic component 21, an encapsulation layer 25, a second circuit structure 26, at least one second electronic component 22, a packaging layer 24, and a shielding layer 29, 29′, 29″.

The first circuit structure 20 has opposing first and second sides 20a and 20b, and a plurality of conductive pillars 23 are disposed on the first side 20a and electrically connected to the first circuit structure 20.

The first electronic component 21 is disposed on the first side 20a of the first circuit structure 20, and combined with a plurality of conductive members 212.

The encapsulation layer 25 is formed on the first side 20a of the first circuit structure 20, and encapsulates the first electronic component 21 and the conductive pillars 23, with end surfaces of the conductive pillars 23 and end surfaces of the conductive members 212 exposed from the encapsulation layer 25.

The second circuit structure 26 is formed on the encapsulation layer 25, and electrically connected to the conductive pillars 23 and the conductive members 212 of the first electronic component 21.

The second electronic component 22 is disposed on the second side 20b of the first circuit structure 20.

The packaging layer 24 is formed on the second side 20b of the first circuit structure, and encapsulates the second electronic component 22.

The shielding layer 29, 29′, 29″ is formed on the packaging layer 24, and extends to a side surface of the first circuit structure 20, a side surface of the encapsulation layer 25, and a side surface of the second circuit structure 26.

In an embodiment, the shielding layer 29 is electrically connected to the first circuit structure 20.

In an embodiment, the shielding layer 29′ is electrically connected to the second circuit structure 26.

In an embodiment, the shielding layer 29″ is electrically connected to the first circuit structure 20 and second circuit structure 26.

In an embodiment, the second circuit structure 26 is exposed from the packaging layer 24.

In an embodiment, the electronic package 2 further comprises a plurality of conductive elements 27′ formed on the second circuit structure 26.

The present disclosure further provides an electronic package 2′, comprising: a first circuit structure 20, a first electronic component 21, an encapsulation layer 25, a second circuit structure 26, and a shielding layer 29.

The shielding layer 29 is formed on the second side 20b of the first circuit structure 20, and extends to a side surface of the first circuit structure 20, a side surface of the encapsulation layer 25, and a side surface of the second circuit structure 26.

Given the foregoing, in an electronic package and a method for fabricating the same according to the present disclosure, the formation of the shielding layer prevents the first electronic component and/or the second electronic component from being affected by EMI, when the electronic package is in operation. Therefore, the electronic package can have its electric functionalities functioning normally.

It will be apparent to those skilled in the art that various modifications and variations can be made to the disclosed embodiments. It is intended that the specification and examples be considered as exemplary only, with a true scope of the disclosure being indicated by the following claims and their equivalents.

1-12. (canceled)

13. A method for fabricating an electronic package, comprising:
providing a first circuit structure having opposing first and second sides;
forming a conductive pillar on the first side of the first circuit structure, with the conductive pillar electrically connected to the first side of the first circuit structure;
disposing a first electronic component on the first side of the first circuit structure;
forming on the first side of the first circuit structure an encapsulation layer encapsulating the first electronic component and the conductive pillar, with a portion of a surface of the first electronic component and an end surface of the conductive pillar exposed from the encapsulation layer;
forming a second circuit structure on the encapsulation layer, with the second circuit structure electrically connected to the conductive pillar and the first electronic component;
disposing a second electronic component on the second side of the first circuit structure;
forming on the second side of the first circuit structure a packaging layer encapsulating the second electronic component; and
forming on the packaging layer a shielding layer extending to a side surface of the first circuit structure, a side surface of the encapsulation layer, and a side surface of the second circuit structure.

14. The method of claim 13, wherein the shielding layer is electrically connected to at least one of the first circuit structure and the second circuit structure.

15. The method of claim 13, wherein the first electronic component has opposing active and inactive surfaces, and the inactive surface of the first electronic component is combined with the first side of the first circuit structure.

16. The method of claim 15, further comprising disposing a plurality of electrode pads on the active surface of the first electronic component.

17. The method of claim 16, further comprising a conductive member formed on one of the electrode pads.

18. The method of claim 17, wherein an end surface of the conductive member is exposed from the encapsulation layer.

19. The method of claim 13, wherein the second circuit structure is exposed from the packaging layer.

20. The method of claim 13, further comprising forming a plurality of conductive elements on the second circuit structure.
